(19) United States
(12) Patent Application Publication
(10) Pub. No.: US 2008/0272445 A1
(43) Pub. Date: Nov. 6, 2008

(54) LOW-K DISPLACER FOR OVERLAP CAPACITANCE REDUCTION

(75) Inventor: Thomas W. Dyer, Pleasant Valley, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: International Business Machines Corporation, Armonk, NY (US)

(21) Appl. No.: 11/687,865

(22) Filed: Mar. 19, 2007

(51) Int. Cl. H01L 21/336

(52) U.S. Cl. 257/412

(57) ABSTRACT

Source/drain extensions and source and drain regions are formed in a semiconductor substrate utilizing an optional temporary first gate spacer and a temporary second gate spacer. After forming a gate silicide and a source and drain silicide in a silicidation process, the optional temporary first gate spacer and a temporary second gate spacer are removed. Low-k dielectric material is disposed directly on the sidewalls of the gate electrode. The low-k dielectric material may form a portion of a lower gate spacer. Alternatively, the low-k dielectric material may form a layer that contacts and covers the source and drain regions. The low-k material displaces the optional temporary first gate spacer and the temporary second gate spacer to lower the overlap capacitance between the gate electrode and the source/drain extensions. A continuous mobile ion diffusion barrier dielectric layer is formed over the low-k material.

### FIELD OF THE INVENTION

The present invention relates to semiconductor structures, and particularly to semiconductor structures with reduced overlap capacitance between source/drain extensions and a gate electrode in a metal-oxide-semiconductor field effect transistor (MOSFET) and methods of manufacturing the same.

### BACKGROUND OF THE INVENTION

High gate-to-source/drain overlap capacitance in a metal-oxide-semiconductor field effect transistor (MOSFET) has an adverse effect on device performance. The gate-to-source/drain overlap capacitance, or more precisely, the overlap capacitance between the gate electrode and the source/drain extensions, has two components. The first component is the overlap capacitance between the gate electrode and the portions of the source/drain extensions under the gate dielectric. The second component is the overlap capacitance between the gate electrode and the portions of the source/drain extensions outside the overlap area with the gate electrode. The fringe electric fields at the edges of the gate electrode pass through a gate spacer, which comprises a dielectric material located on the sidewalls of the gate electrode, and capacitively couple the gate electrode with the source/drain extensions.

Referring to FIG. 1, a prior art MOSFET structure illustrates the two components of the overlap capacitance discussed above. The prior art MOSFET comprises a gate dielectric 20 disposed on a semiconductor substrate 10, a gate conductor 22 disposed on the gate dielectric 20, an optional first gate spacer 30, a second spacer 40, source/drain extensions 32, source and drain regions 42, a gate silicide 52 formed on the gate conductor 22, a source and drain silicide 54 formed on the source and drain regions 42, a mobile ion diffusion barrier dielectric layer 80, and a middle-of-line dielectric 90. The gate conductor 22 and the gate silicide 52 collectively comprise a gate conductor 58.

The semiconductor substrate is typically doped with dopants of a first conductivity type at a doping concentration in the range from about 1.0×10¹⁶/cm³ to about 1.0×10¹⁹/cm³. The source/drain extensions 32 are doped with dopants of a second conductivity type, which is the opposite type to the first conductivity type, at a doping concentration on the order of about 1.0×10²⁰/cm³. The source and drain regions 42 are doped with dopants of the second conductivity type at a doping concentration on the order of about 5.0×10²⁰/cm³.

The gate dielectric 20 may be a silicon oxide or a stack of multiple dielectric materials containing silicon oxide. In this case, the thickness of the gate dielectric 20 is on the order of about 1 nm to about 6 nm. Alternatively, the gate dielectric 20 may be a high-k dielectric material. In this case, the thickness of the gate dielectric is typically greater than the thickness of an equivalent gate oxide, and is typically in the range from about 2 nm to about 10 nm. The gate conductor 22 typically comprises a silicon containing material and may be, for example, doped polysilicon.

The optional first gate spacer 30 typically comprises silicon oxide, which may be formed either by thermal oxidation of sidewalls of the gate conductor 58, deposition of a thin low temperature oxide followed by a reactive ion etch, or a combination of both. The thickness of the optional first gate spacer 30 is in the range from about 3 nm to about 15 nm, and typically in the range from about 6 nm to about 12 nm.

The second spacer 40 typically comprises silicon nitride, and is formed by a conformal deposition of a silicon nitride layer followed by a reactive ion etch (RIE). The thickness of the second gate spacer 40 is in the range from about 20 nm to about 100 nm, and typically in the range from about 30 nm to about 80 nm.

The gate silicide 52 and the source and drain silicide 54 are formed by a silicidation process. The mobile ion diffusion barrier dielectric layer 80 is formed over the entire surface of the semiconductor substrate 10 to prevent diffusion of mobile ions from the MOL dielectric 90 or from back-end-of-line (BEOL) dielectric layers into the semiconductor substrate 10. The mobile ion diffusion barrier dielectric layer 80 typically comprises silicon nitride and may apply stress to the underlying structures. The MOL dielectric 90 typically comprises silicon oxide, such as undoped silicate glass (USG), fluorosilicate glass (FSG), or borophosphosilicate glass (BPSG).

As for the first component of the overlap capacitance, the thinness of the gate dielectric 20, i.e., the thickness only being in the range from about 1 nm to about 6 nm, contributes to a substantial value for the first component. However, the overlap area between the gate conductor 22 and the source/drain extensions 32 is relatively small. For example, the overlap area typically has a length of less than 10 nm. Also, the dielectric constant has a relatively low value of about 3.9 in the case of a silicon oxide gate dielectric. These two factors help limit the first component of the overlap capacitance. In the case of a gate dielectric 20 comprising a high-k material, the high dielectric constant is typically partially compensated for by a greater thickness, for example, in the range from about 3 nm to about 15 nm.

As for the second component of the overlap capacitance, the average distance between the gate conductor 22 and the source/drain extensions 32 are greater than the thickness of the gate dielectric 20. However, large surface areas of a parasitic capacitor structure, that is, the entire sidewall surface area of the gate conductor 22 adjacent to the source/drain extensions 32 and the area of the source/drain extensions 32 outside the directly overlapped area under the gate conductor 22, are involved in the capacitive coupling. Further, silicon nitride has a relatively high dielectric constant of about 7.5. Compared with the dielectric constant of about 3.9 for silicon oxide, the higher dielectric constant of silicon nitride contributes to a substantial value in the second component of the overlap capacitance.

The replacement of the silicon nitride second spacer with a silicon oxide second spacer may be achieved to reduce the second component of the overlap capacitance, as is known in the prior art. Even in this case, however, the second component of the overlap capacitance still may be substantial.

Referring to FIG. 2, percentage changes in overlap capacitance for two hypothetical structures are shown as a function of the dielectric constant of the second spacer 40. The first hypothetical structure comprises a MOSFET gate structure with a 10 nm thick optional first gate spacer 30 consisting of silicon oxide with a dielectric constant of 3.9 and has a second gate spacer 40 with a variable dielectric constant, k(spacer2). The second hypothetical structure comprises a MOSFET gate structure without an optional first gate spacer 30 and only with a second gate spacer 40 with a variable dielectric constant, k(spacer2), that is, the second gate spacer 40 is located directly on the gate electrode 58. The value of the overlap capacitance for the first hypothetical structure in which the second spacer 40 consists of silicon nitride with a dielectric constant 7.5 is the reference overlap capacitance value against which percentage changes in the overlap capacitance in the various hypothetical structures are plotted in FIG. 2.

FIG. 2 shows that use of silicon oxide for the second gate spacer 40 would result in about a 7% decrease in the overlap capacitance in the first hypothetical structure. Use of a low-k dielectric material with a dielectric constant of about 2.2˜2.5 for the second gate spacer 40 would result in about a 12%˜13% decrease in the overlap capacitance in the first hypothetical structure. Use of a low k-material with a dielectric constant of about 2.2˜2.5 for the second gate spacer 40 would result in about a 20%˜23% decrease in the overlap capacitance in the second structure, that is, if the optional first gate spacer 30 is eliminated.

While use of a low-k dielectric material for the second gate spacer may be tempting, the implementation of low-k dielectric material in a physical gate structure, i.e., in a low-k gate spacer, faces difficulties since low-k dielectric materials are not conformal, and therefore, is not conducive to spacer formation by conventional processes. For example, the step coverage of chemical vapor deposition (CVD) low-k materials are so low that obtaining sufficient thickness of CVD low-k material on sidewalls of a gate electrode is difficult. Spin-on low-k dielectric material is typically self-planarizing, and therefore, formation of spin-on low-k material spacers is also difficult.

Therefore, there exists a need to provide a semiconductor structure with a reduced overlap capacitance between a gate electrode and source/drain extensions, and particularly, with a low-k material spacer on the sidewalls of a gate electrode, and methods of manufacturing the same.

### SUMMARY OF THE INVENTION

The present invention addresses the needs described above by providing a semiconductor structure with a low-k material spacer on the sidewalls of a gate electrode and methods of manufacturing the same.

According to the present invention, source/drain extensions and source and drain regions are formed in a semiconductor substrate utilizing an optional temporary first gate spacer and a temporary second gate spacer. After forming a gate silicide and a source and drain silicide in a silicidation process, the optional temporary first gate spacer and a temporary second gate spacer are removed. Low-k dielectric material is disposed directly on the sidewalls of the gate electrode. The low-k dielectric material may form a portion of a lower gate spacer.

Alternatively, the low-k dielectric material may form a layer that contacts and covers the source and drain regions. The low-k material displaces the optional temporary first gate spacer and the temporary second gate spacer to lower the overlap capacitance between the gate electrode and the source/drain extensions. A continuous mobile ion diffusion barrier dielectric layer is formed over the low-k material. The low-k material forms a displacer structure that replaces at least the optional temporary first gate spacer and the temporary second gate spacer and provides lower overlap capacitance.

According to a first group of embodiments of the present invention, a metal-oxide-semiconductor field effect transistor structure comprises:

a low-k dielectric layer having a first dielectric constant of about 3.0 or less and contacting a sidewall of a gate electrode and source/drain extensions; and

a mobile ion diffusion barrier dielectric layer contacting the low-k dielectric layer and the gate electrode.

The low-k dielectric layer may contact a top surface of the gate electrode.

Alternatively, the mobile ion diffusion barrier dielectric layer contacts a top surface of the gate electrode. According to an embodiment, the mobile ion diffusion barrier dielectric layer contacts the sidewall of the gate electrode. According to another embodiment, the MOSFET structure further comprises an upper gate spacer having a second dielectric constant of greater than 3.0 and contacting the sidewall of the gate electrode. According to yet another embodiment, the MOSFET structure further comprises an upper gate spacer having a second dielectric constant of greater than 3.0, contacting the low-k dielectric layer, and disjoined from, i.e., not adjoined to, the sidewall of the gate electrode.

According to a second group of embodiments, a metal-oxide-semiconductor field effect transistor (MOSFET) structure comprises:

a low-k dielectric lower spacer having a first dielectric constant of about 3.0 or less and contacting a sidewall of a gate electrode and source/drain extensions; and

an upper gate spacer having a second dielectric constant of greater than 3.0 and contacting the low-k dielectric spacer.

The MOSFET structure may further comprise a mobile ion diffusion barrier dielectric layer contacting a gate silicide on the gate electrode.

According to an embodiment, the low-k dielectric lower spacer comprises a spin-on low-k dielectric material. In this case, the upper gate spacer may contact the sidewall of the gate electrode.

According to another embodiment, the low-k dielectric lower spacer comprises a chemical vapor deposition (CVD) low-k dielectric material. In this case, the low-k dielectric lower spacer may be L-shaped and may contact the sidewall of the gate electrode. Further, the upper gate spacer is disjoined from, i.e., not adjoined to, the sidewall of the gate electrode.

According to the present invention, a method of manufacturing a semiconductor structure comprises:

forming a gate electrode having a gate silicide, a temporary gate spacer located on the gate electrode, and a source and drain silicide on a semiconductor substrate;

removing the temporary gate spacer and exposing at least one sidewall of the gate electrode;

forming a low-k dielectric layer having a dielectric constant of about 3.0 or less directly on the source/drain extensions and directly on at least a portion of the gate electrode; and

forming a mobile ion diffusion barrier dielectric layer directly contacting at least a portion of the low-k dielectric layer.

The low-k dielectric layer may comprise a spin-on low-k dielectric material. The mobile ion diffusion barrier dielectric layer may be formed directly on the at least one sidewall of the gate electrode and a top surface of the gate electrode. Alternatively, an upper gate spacer having a dielectric constant of greater than 3.0 may be formed directly on the low-k dielectric layer and directly on the at least one sidewall of the gate electrode. In this case, a low-k dielectric lower gate spacer may be formed out of the low-k dielectric layer, wherein the low-k dielectric lower gate spacer contacts the at least one sidewall of the gate electrode, source/drain extensions, and the upper gate spacer.

The low-k dielectric layer may comprise a chemical vapor deposition (CVD) low-k dielectric material. An upper gate spacer having a dielectric constant of greater than 3.0 may further be formed directly on the low-k dielectric layer, wherein the upper gate spacer is disjoined from, i.e., not adjoined to, the at least one sidewall of the gate electrode. In this case, an L-shaped low-k dielectric lower gate spacer may be formed out of the low-k dielectric layer, wherein the L-shaped low-k dielectric lower gate spacer contacts the at least one sidewall of the gate electrode, source/drain extensions, and the upper gate spacer.

### BRIEF DESCRIPTION OF THE DRAWINGS

FIG. 1 is a vertical cross-sectional view of an exemplary prior art MOSFET structure illustrating two components of the overlap capacitance between a gate electrode 58 and source/drain extensions 32.

FIG. 2 is a graph showing percentage changes in overlap capacitance for two hypothetical structures similar to the exemplary prior art MOSFET structure of FIG. 1 as a function of the dielectric constant of the second spacer 40.

FIGS. 3-5 are sequential vertical cross-sectional views of exemplary semiconductor structures during common processing steps according to a first through fourth embodiments of the present invention.

FIGS. 6-7 are sequential vertical cross-sectional views of exemplary semiconductor structures during common processing steps according to the first through third embodiments of the present invention.

FIGS. 8-9 are sequential vertical cross-sectional views of a first exemplary semiconductor structure according to the first embodiment of the present invention.

FIGS. 10-11 are sequential vertical cross-sectional views of exemplary semiconductor structures during common processing steps according to the second and third embodiments of the present invention.

FIGS. 12-13 are sequential vertical cross-sectional views of a second exemplary semiconductor structure according to the second embodiment of the present invention.

FIGS. 14-16 are sequential vertical cross-sectional views of a third exemplary semiconductor structure according to the third embodiment of the present invention.

FIGS. 17-20 are sequential vertical cross-sectional views of a fourth exemplary semiconductor structure according to the fourth embodiment of the present invention.

### DETAILED DESCRIPTION OF THE INVENTION

As stated above, the present invention relates to semiconductor structures with reduced overlap capacitance between source/drain extensions and a gate electrode in a metal-oxide-semiconductor field effect transistor (MOSFET) and methods of manufacturing the same, which are now described in detail with accompanying figures. It is noted that like and corresponding elements are referred to by like reference numerals.

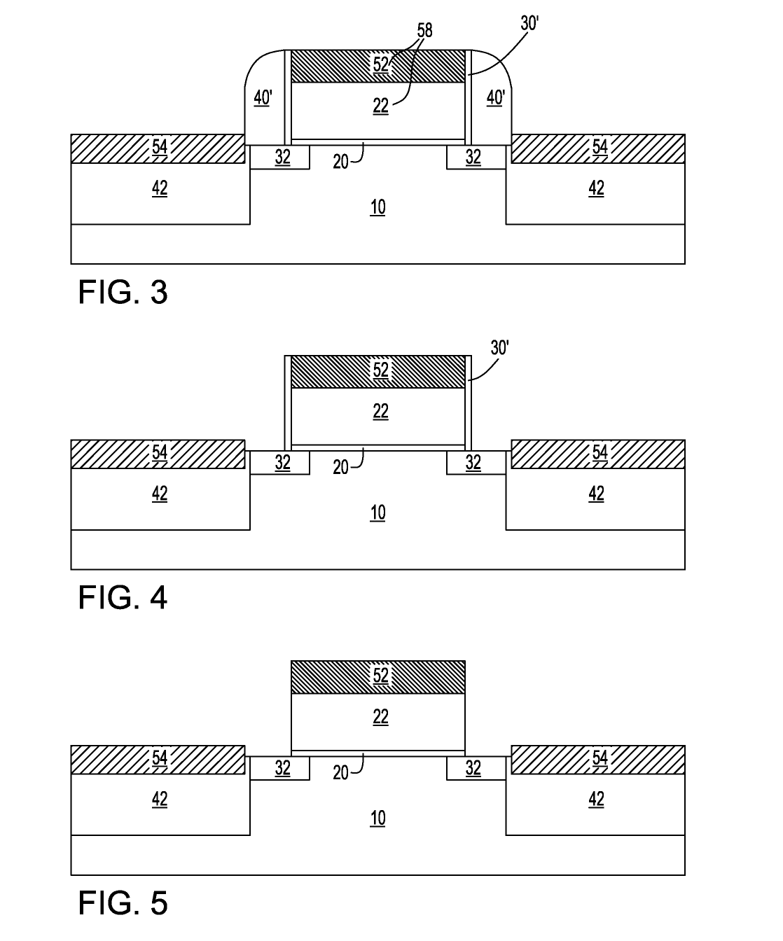

Referring to FIG. 3, a semiconductor according to the present invention comprises a metal-oxide-semiconductor field effect transistor (MOSFET) having a gate dielectric 20 disposed on a semiconductor substrate 10, a gate conductor 22 disposed on the gate dielectric 20, an optional temporary first gate spacer 30′, a temporary second gate spacer 40′, source/drain extensions 32, source and drain regions 42, a gate silicide 52 formed on the gate conductor 22, a source and drain silicide 54 formed on the source and drain regions 42, a mobile ion diffusion barrier dielectric layer 80, and a middle-of-line (MOL) dielectric 90. The gate conductor 22 and the gate silicide 52 collectively comprise a gate conductor 58.

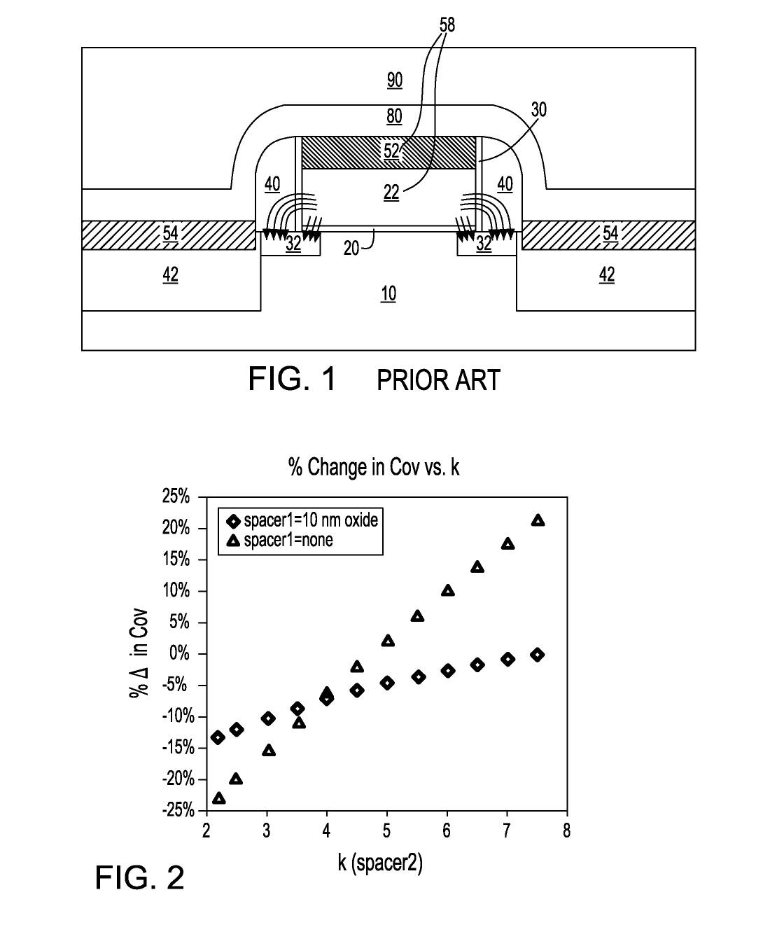

The semiconductor structure, or more specifically, the MOSFET structure according to the present invention at this stage of processing sequence is substantially identical to the prior art structure except that a mobile ion diffusion barrier dielectric layer 80 and an MOL dielectric 90 are not present in the structure as shown in FIG. 3. Also, the optional temporary first gate spacer 30′ and the temporary second gate spacer 40′ are utilized as shown in FIG. 3 instead of the optional first gate spacer 30 and the second gate spacer 40 in the exemplary MOSFET structure according to the prior art shown in FIG. 1. The differences between the gate spacers (30, 40) and temporary gate spacers (30′, 40′) are only in the labeling and not in substance. In other words, the temporary gate spacers (30′, 40′) according to the present invention are “temporary” only because they are subsequently removed, as will be described herebelow. The MOSFET structure according to the present invention may employ any prior art gate spacer structures provided that the gate spacer structures can be subsequently removed. Therefore, the MOSFET structure according to the present invention is also compatible with other prior art structures that have any number of removable gate spacers having dielectric constants greater than 3.0. Further, application of the present invention to MOSFET structures with different source and drain configurations, e.g., raised source and drain regions, is herein explicitly contemplated.

Referring to FIG. 4, the temporary second gate spacer 40′ is removed by a first etch. The first etch may be a wet etch or a reactive ion etch. Preferably, the first etch is selective to the underlying semiconductor material in the source/drain extensions 32, the silicide material in the gate silicide 52 and in the source and drain silicide 54, and the optional temporary first gate spacer 30′.

Referring to FIG. 5, the optional temporary first gate spacer 30′ is removed by a second etch. The second etch is preferably a wet etch. Preferably, the first etch is selective to the underlying semiconductor material in the source/drain extensions 32 and the silicide material in the gate silicide 52 and in the source and drain silicide 54. If the optional temporary first gate spacer 30′ is not present, the first etch produces the structure shown in FIG. 5. The source and drain regions 42 may be recessed or raised relative to the gate dielectric 20. For MOSFET structures comprising more than two “temporary” gate spacers, all temporary gate spacers are removed at this stage of processing sequence.

Referring to FIG. 6, a spin-on low-k dielectric material is applied to the semiconductor substrate to form a spin-on low-k dielectric layer 60. The dielectric constant k of the spin-on low-k dielectric layer 60 is about 3.0 or less, preferably less than about 2.8, and more preferably less than about 2.5. The spin-on low-k dielectric material can be porous or nonporous. An example of the spin-on low-k dielectric material is a thermosetting polyarylene ether, which is also commonly referred to as “Silicon Low-K”, or “SiLK.” The term “polyarylene” is used herein to denote aryl moieties or inertly substituted aryl moieties which are linked together by bonds, fused rings, or inert linking groups such as oxygen, sulfur, sulfone, sulfoxide, carbonyl, etc.

The spin-on low-k dielectric layer 60 has a thickness, as measured above the top of source and drain regions 42, in the range from about 50 nm to about 1 μm, with a thickness from 100 to about 500 nm being more typical. The thickness of the spin-on low-k dielectric layer 60 may be tuned by controlling the viscosity of the spin-on low-k dielectric material during the application.

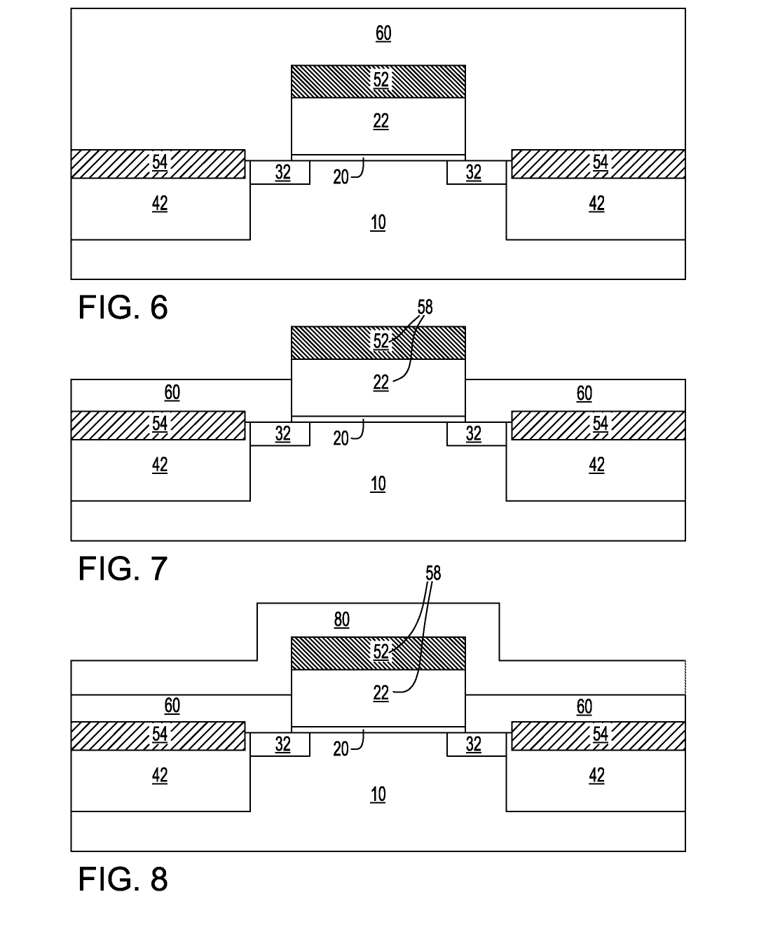

Referring to FIG. 7, the spin-on low-k dielectric layer 60 is recessed by a recess etch such that the top surface of the spin-on low-k dielectric layer is located below the top surface of the gate electrode 58, and preferably below the top surface of the gate conductor 22. The recess etch is preferably selective to the gate silicide 52 and the gate conductor 22. The gate conductor 22 has a thickness ranging from about 50 nm to about 200, and typically from about 80 nm to about 150 nm. After recessing, the spin-on low-k dielectric layer 60 has a thickness ranging from about 5 nm to about 200 nm, and preferably in the range from about 20 nm to about 100 nm. Instead of depositing a thick spin-on low-k dielectric layer and recessing it as shown in FIGS. 6 and 7, a thinner spin-on low-k dielectric layer with a final target thickness may be deposited directly as shown in FIG. 7.

At least an upper portion of a sidewall of the gate electrode 58 and the top surface of the gate electrode 58 are exposed by the recess etch. Highly preferably, upper portions of both sidewalls of the gate electrode 58 are exposed by the recess etch. The exposed portion of the gate electrode 58 protrudes above the top surface of the recessed spin-on low-k dielectric layer 60. Topologically, the spin-on low-k dielectric layer 60 has a hole corresponding to the gate electrode 58 after the recess etch. According to the present invention, the spin-on low-k dielectric layer 60 directly contacts at least one sidewall of the gate electrode 58 and the source/drain extensions 32. Highly preferably, the spin-on low-k dielectric layer directly contacts both sidewalls of the gate electrode 58.

According to a first embodiment of the present invention, a mobile ion diffusion barrier dielectric layer 80 is deposited directly on the spin-on low-k dielectric layer 60, the at least one sidewall of the gate electrode 58, and the top surface of the gate electrode 58 as shown in FIG. 8. The top surface of the gate electrode 58 preferably comprises a gate silicide 52. The mobile ion diffusion barrier dielectric layer 80 prevents mobile ions, such as Na⁺ and K⁺, from diffusing from a middle-of-line (MOL) dielectric or a back-end-of-line (BEOL) dielectric into the semiconductor substrate 10. The mobile ion diffusion barrier dielectric layer 80 typically comprises silicon nitride with a thickness in the range from about 10 nm to about 80 nm, and typically in the range from about 30 nm to about 60 nm. The mobile ion diffusion barrier dielectric layer 80 may apply a stress to the structures therebelow.

Referring to FIG. 9, a middle-of-line (MOL) dielectric 90 is thereafter deposited on the mobile ion diffusion barrier dielectric layer 80. The MOL dielectric 90 typically comprises silicon oxide, such as undoped silicate glass (USG), fluorosilicate glass (FSG), or a borophosphosilicate glass (BPSG). Due to the underlying topography caused by protruding structures such as the gate electrode 58, the MOL dielectric 90 has topographical height variations as deposited. Consequently, the MOL dielectric 90 is typically planarized, for example, by chemical mechanical polishing (CMP). After the planarization, contact vias (not shown) are formed in the MOL dielectric 90. Back-end-of-line (BEOL) metal wiring (not shown) is formed thereafter above the MOL dielectric 90.

The structure according to the first embodiment of the present invention as shown in FIG. 9 comprises the spin-on low-k dielectric layer 60, which is a low-k dielectric layer having a first dielectric constant of about 3.0 or less and contacting a sidewall of a gate electrode 58 and source/drain extensions 32; and a mobile ion diffusion barrier dielectric layer 80 contacting the spin-on low-k dielectric layer 60. The mobile ion diffusion barrier dielectric layer 80 contacts the top surface of the gate electrode 58 and the sidewalls of the gate electrode 58.

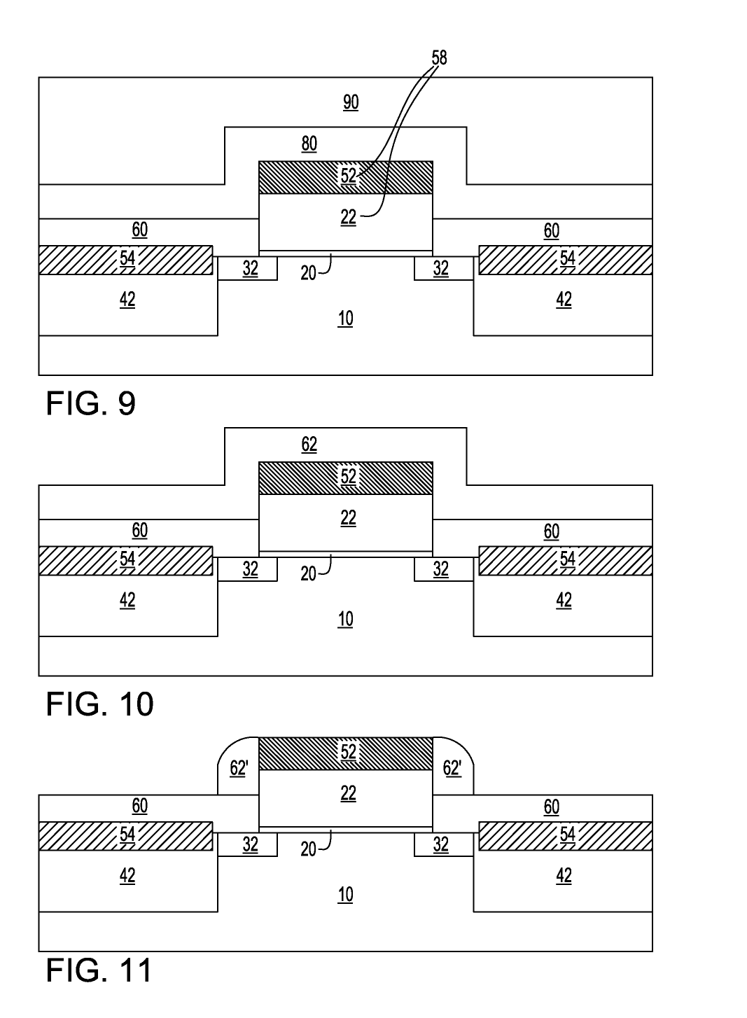

According to a second embodiment and a third embodiment of the present invention, after the processing steps corresponding to FIG. 7, a conformal dielectric layer 62 is deposited directly on the spin-on low-k dielectric layer 60, the at least one sidewall of the gate electrode 58, and a top surface of the gate electrode 58 as shown in FIG. 10. The top surface of the gate electrode 58 preferably comprises a gate silicide 52. The conformal dielectric layer 62 may comprise silicon nitride, silicon oxide, silicon oxide, or a stack thereof. The conformal dielectric layer 62 is preferably formed by chemical vapor deposition, such as low pressure chemical vapor deposition (LPCVD), plasma enhanced chemical vapor deposition (PECVD), or sub-atmospheric chemical vapor deposition (SACVD). The conformal dielectric layer 62 is preferably conformal, i.e., has substantially the same thickness on vertical sidewalls as on horizontal surfaces. The conformal dielectric layer 62 has a thickness in the range from about 10 nm to about 120 nm, and preferably from about 30 nm to about 90 nm.

Referring to FIG. 11, a reactive ion etch (RIE) is performed to form an upper gate spacer 62′ out of the conformal dielectric layer 62. Preferably, the reactive ion etch process is selective to the spin-on low-k dielectric layer 60 and to the gate silicide 52. Typically, the thickness of the upper gate spacer 62′ is substantially the same as the thickness of the conformal dielectric layer 62.

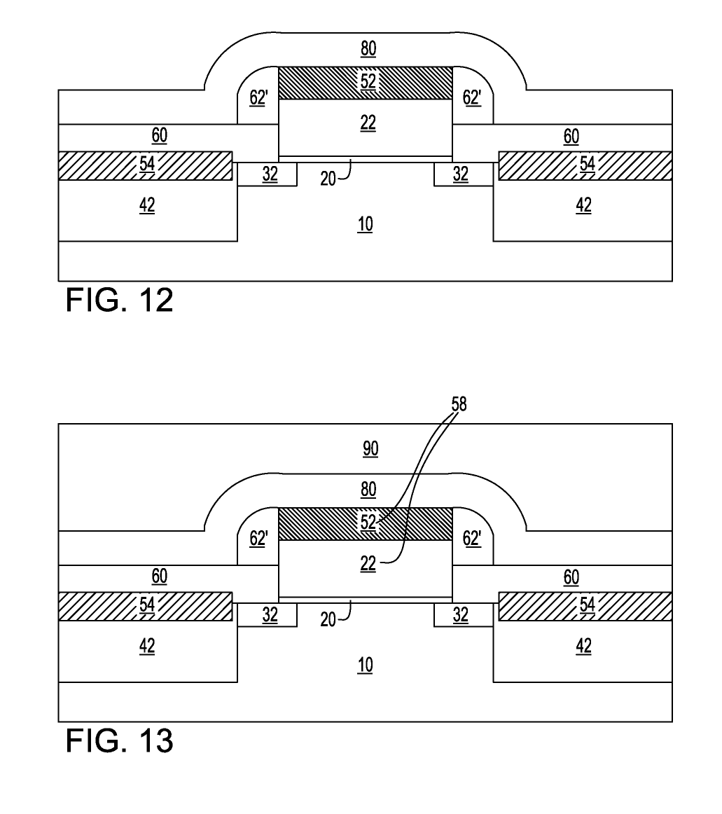

According to the second embodiment of the present invention, a mobile ion diffusion barrier dielectric layer 80 is deposited directly on the spin-on low-k dielectric layer 60, the upper gate spacer 62′, and the top surface of the gate electrode 58 as shown in FIG. 12. The properties of the mobile ion diffusion barrier dielectric layer 80 are the same as described in the paragraphs above for the first embodiment of the present invention.

Referring to FIG. 13, a middle-of-line (MOL) dielectric 90 is thereafter deposited on the mobile ion diffusion barrier dielectric layer 80. The properties of the MOL dielectric 90 are the same as described in the paragraphs above for the first embodiment of the present invention.

The structure according to the second embodiment of the present invention as shown in FIG. 13 comprises the spin-on low-k dielectric layer 60, which is a low-k dielectric layer having a first dielectric constant of about 3.0 or less and contacting a sidewall of a gate electrode 58 and source/drain extensions 32; and a mobile ion diffusion barrier dielectric layer 80 contacting the low-k dielectric layer. The mobile ion diffusion barrier dielectric layer 80 contacts the top surface of the gate electrode 58. An upper gate spacer 62′ having a second dielectric constant of greater than 3.0 contacts the at least one sidewall of the gate electrode 58. Highly preferably, the upper gate spacer 62′ contacts both sidewalls of the gate electrode 58. The mobile ion diffusion barrier dielectric layer 80 is disjoined from, i.e., not adjoined to, the gate conductor 22, which is located directly beneath the gate silicide 52.

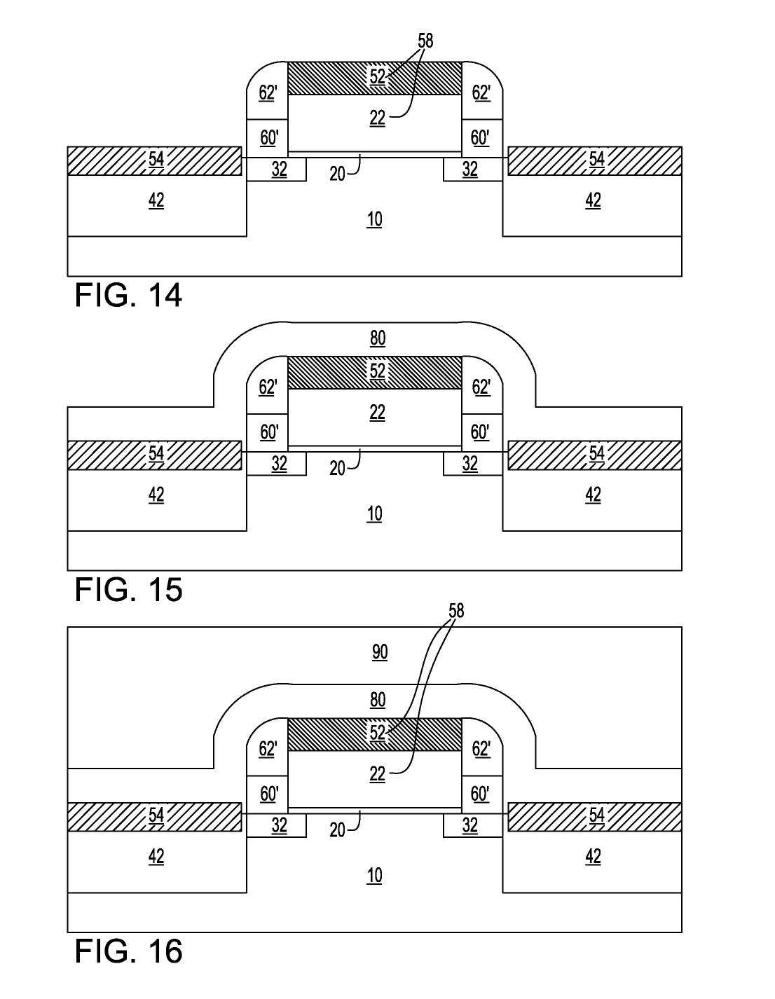

According to the third embodiment of the present invention, after the processing steps corresponding to FIG. 11, a low-k dielectric reactive ion etch is employed to etch the portions of the spin-on low-k dielectric layer 60 that are not masked by the upper gate spacer 62′ as shown in FIG. 14. The low-k dielectric reactive ion etch etches the spin-on low-k dielectric material selective to the upper gate spacer 62′, the gate silicide 52, and the source and drain silicide 54. A low-k dielectric lower gate spacer 60′ is formed out of the remaining spin-on low-k dielectric layer 60 under the upper gate spacer 62′. The outer surface of the low-k dielectric lower gate spacer 60′ may be substantially coincident with the outer surface of the upper gate spacer 62′, or alternately, may be recessed toward the gate electrode 58 relative to the outer surface of the upper gate spacer 62′. The low-k dielectric lower gate spacer 60′ directly contacts the source/drain extensions 32.

Referring to FIG. 15, a mobile ion diffusion barrier dielectric layer 80 is deposited directly on the source and drain silicide 54, the low-k dielectric lower gate spacer 60′, the upper gate spacer 62′, and the top surface of the gate electrode 58. The properties of the mobile ion diffusion barrier dielectric layer 80 are the same as described in the paragraphs above for the first embodiment of the present invention.

Referring to FIG. 16, a middle-of-line (MOL) dielectric 90 is thereafter deposited on the mobile ion diffusion barrier dielectric layer 80. The properties of the MOL dielectric 90 are the same as described in the paragraphs above for the first embodiment of the present invention.

The structure according to the third embodiment of the present invention as shown in FIG. 16 comprises the low-k dielectric lower gate spacer 60′ having a dielectric constant of about 3.0 or less and contacting a sidewall of a gate electrode 58 and source/drain extensions 32; and

an upper gate spacer 62′ having a dielectric constant of greater than 3.0 and contacting the sidewall of a gate electrode 58 and the low-k dielectric lower gate spacer 60′. The mobile ion diffusion barrier dielectric layer 80 contacts the top surface of the gate electrode 58, the upper gate spacer 62′, the low-k dielectric lower gate spacer 60′, and the source and drain silicide 54. Highly preferably, the upper gate spacer 62′ contacts both sidewalls of the gate electrode 58 and the low-k dielectric lower gate spacer 60′ contacts both sidewalls of the gate electrode 58.

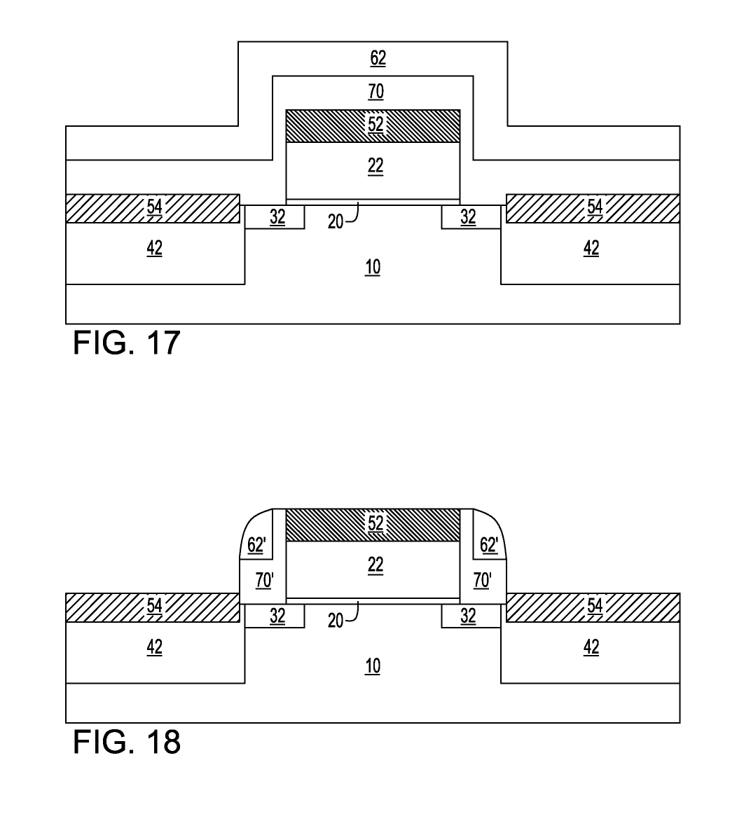

According to a fourth embodiment of the present invention, after the processing steps corresponding to FIG. 5, a chemical vapor deposition (CVD) low-k dielectric material is deposited directly on the source and drain silicide 54, source/drain extensions 32, at least one sidewall of the gate electrode 58, and on the top surface of the gate electrode 58 to form a CVD low-k dielectric layer 70. Highly preferably, the CVD low-k dielectric layer 70 contacts both sidewalls of the gate electrode 58. The top surface of the gate electrode 58 preferably comprises a gate silicide 52 as shown in FIG. 17.

The dielectric constant k of the CVD low-k dielectric layer 70 is about 3.0 or less, preferably less than about 2.8, and more preferably less than about 2.5. The CVD low-k dielectric material can be porous or nonporous. Composition and deposition methods of the CVD low-k dielectric material are well known in the art. For example, the CVD low-k dielectric material may be a SiCOH dielectric containing a matrix of a hydrogenated oxidized silicon carbon material (SiCOH) comprising atoms of Si, C, O and H in a covalently bonded tri-dimensional network. Such CVD low-k dielectric material has a dielectric constant of not more than about 2.8 and typically comprises between about 5 and about 40 atomic percent of Si; between about 5 and about 45 atomic percent of C; between 0 and about 50 atomic percent of 0; and between about 10 and about 55 atomic percent of H. The tri-bonded network may include a covalently bonded tri-dimensional ring structure comprising Si—O, Si—C, Si—H, C—H and C—C bonds.

Further, the CVD low-k dielectric material may comprise F and N and may optionally have the Si atoms partially substituted by Ge atoms. The CVD low-k dielectric material may contain molecular scale voids (i.e., nanometer-sized pores) of between about 0.3 to about 50 nanometers in diameter, and most preferably between about 0.4 and about 10 nanometers in diameter, further reducing the dielectric constant of the film 12 to values below about 2.0. The nanometer-sized pores of the low k dielectric film 12 occupy a volume of between about 0.5% and about 50% of a volume of the material.

Organosilicon precursors used in forming the CVD low-k dielectric layer 70 may comprise organic molecules with ring structures comprising SiCOH components such as 1,3,5,7-tetramethylcyclotetrasiloxane (“TMCTS” or “C₄H₁₆O₄Si₄”), octamethylcyclotetrasiloxane (OMCTS), diethoxymethylsilane (DEMS), dimethyldimethoxysilane (DMDMOS), diethylmethoxysilane (DEDMOS), and related cyclic and non-cyclic silanes, siloxanes and the like. Further, an oxygen source gas such as O₂, CO₂, or a mixture thereof is supplied to a reaction chamber during the deposition of the CVD low-k dielectric layer 70. The optional C source that may be used as well. Typically, the CVD process is a plasma enhanced CVD (PECVD) process with a low RF source and bias power (less than 800 watts for a 200 mm system and at low pressures (on the order of about 50 to about 8000 mTorr) and relatively low temperatures (on the order of less than 420° C.).

Typically, the step coverage of the CVD low-k dielectric layer 70 is on the order of about 33%, i.e., the film thickness on a vertical sidewall is only about ⅓ of the film thickness on a horizontal surface, which is considered very low even for a PECVD process.

A conformal dielectric layer 62 is thereafter deposited directly on the CVD low-k dielectric layer 70. The properties of the conformal dielectric layer 62 are the same as described in the paragraphs above for the second and third embodiments of the present invention.

Referring to FIG. 18, a reactive ion etch (RIE) is performed to form an upper gate spacer 62′ out of the conformal dielectric layer 62. The reactive ion etch process may, or may not, be selective to the underlying CVD low-k dielectric layer 70. Typically, the thickness of the upper gate spacer 62′ is substantially the same as the thickness of the conformal dielectric layer 62. A low-k dielectric reactive ion etch is thereafter employed to etch the portions of the CVD low-k dielectric layer 70 that are not masked by the upper gate spacer 62′ as shown in FIG. 18. The low-k dielectric reactive ion etch etches the CVD low-k dielectric material selective to the upper gate spacer 62′, the gate silicide 52, and the source and drain silicide 54. An L-shaped low-k dielectric lower gate spacer 70′ is formed out of the remaining CVD low-k dielectric layer 70 under the upper gate spacer 62′. According to the fourth embodiment of the present invention, the cross-sectional area of the L-shaped low-k dielectric lower gate spacer 70′ is L-shaped as shown in FIG. 21. The outer surface of the L-shaped low-k dielectric lower gate spacer 70′ may be substantially coincident with the outer surface of the upper gate spacer 62′, or alternately, may be recessed toward the gate electrode 58 relative to the outer surface of the upper gate spacer 62′. The L-shaped low-k dielectric lower gate spacer 70′ directly contacts the source/drain extensions 32.

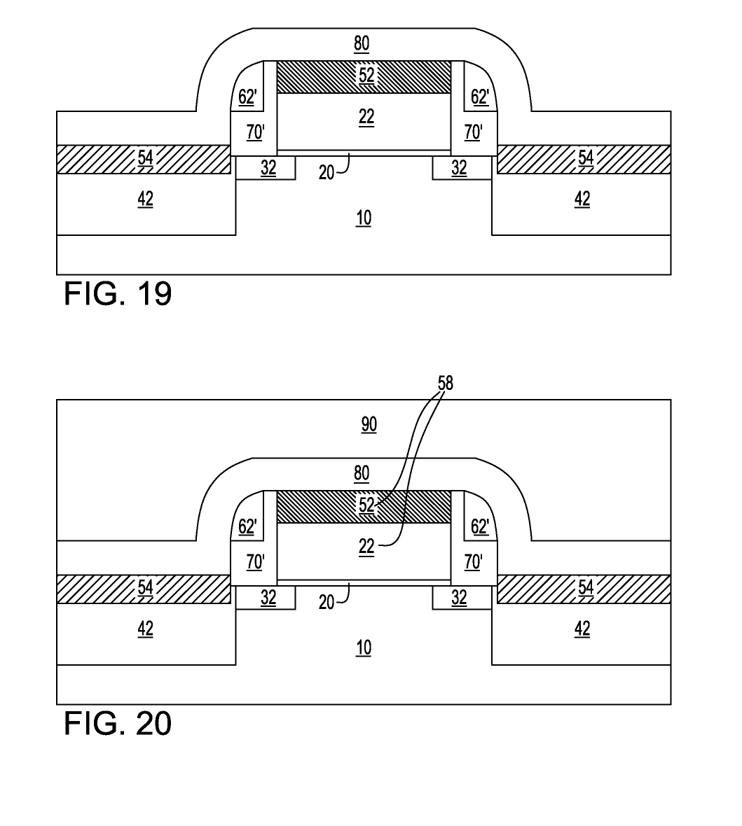

Referring to FIG. 19, a mobile ion diffusion barrier dielectric layer 80 is deposited directly on the source and drain silicide 54, the low-k dielectric lower gate spacer 70′, the upper gate spacer 62′, and the top surface of the gate electrode 58. The properties of the mobile ion diffusion barrier dielectric layer 80 are the same as described in the paragraphs above for the first embodiment of the present invention.

Referring to FIG. 20, a middle-of-line (MOL) dielectric 90 is thereafter deposited on the mobile ion diffusion barrier dielectric layer 80. The properties of the MOL dielectric 90 are the same as described in the paragraphs above for the first embodiment of the present invention.

The structure according to the fourth embodiment of the present invention as shown in FIG. 21 comprises the L-shaped low-k dielectric lower gate spacer 70′, which is a low-k dielectric lower gate spacer having a dielectric constant of about 3.0 or less and contacting a sidewall of a gate electrode 58 and source/drain extensions 32; and an upper gate spacer 62′ having a dielectric constant of greater than 3.0 and contacting the low-k dielectric lower gate spacer 60′. The upper gate spacer 62′ is disjoined from, i.e., does not contact, the sidewall of a gate electrode 58. The mobile ion diffusion barrier dielectric layer 80 contacts the top surface of the gate electrode 58, the upper gate spacer 62′, the low-k dielectric lower gate spacer 60′, and the source and drain silicide 54. Highly preferably, the L-shaped low-k dielectric lower gate spacer 70′ contacts both sidewalls of the gate electrode 58.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

1-20. (canceled)

21. A method of manufacturing a semiconductor structure, comprising:
forming a gate electrode having a gate suicide, a temporary gate spacer located on said gate electrode, and a source and drain suicide on a semiconductor substrate;
removing said temporary gate spacer and exposing at least one sidewall of said gate electrode;
forming a low-k dielectric layer having a dielectric constant of about 3.0 or less and comprising a chemical vapor deposition (CVD) low-k dielectric material on said source/drain extensions and directly on at least a portion of said gate electrode;
forming an L-shaped low-k dielectric lower gate spacer out of said low-k dielectric layer, wherein said L-shaped low-k dielectric lower gate spacer contacts said at least one sidewall of said gate electrode, and source/drain extensions;
forming an upper gate spacer having a dielectric constant of greater than 3.0 directly on a horizontal portion of said L-shaped dielectric lower gate spacer, wherein said upper gate spacer is disjoined from said at least one sidewall of said gate electrode by a vertical portion of the L-shaped dielectric lower gate spacer;
forming a mobile ion diffusion barrier dielectric layer directly on said at least one sidewall of said gate electrode and a top surface of said gate electrode.
